(19) United States
(12) Patent Application Publication
(10) Pub. No.: US 2013/0176224 A1
(43) Pub. Date: Jul. 11, 2013

(54) OPTICAL NAVIGATION SENSOR MODULE OF OPTICAL MOUSE AND METHOD FOR MANUFACTURING THE SAME

(71) Applicant: SHU-WEI CHIU, HSINCHU HSIEN (TW)

(72) Inventor: SHU-WEI CHIU, HSINCHU HSIEN (TW)

(73) Assignee: MILLENNIUM COMMUNICATION CO., LTD., HSINCHU HSIEN (TW)

(21) Appl. No.: 13/344,692

(22) Filed: Jan. 6, 2012

(51) Int. Cl. G06F 3/033; H05K 3/30

(52) U.S. Cl. 345/166; 29/832

(57) ABSTRACT

An optical navigation sensor module of an optical mouse includes a substrate with a lower surface; an image sensor arranged on the lower surface; and a light-emitting chip package using a SMD package electrically connected to the lower surface of the substrate. The light-emitting chip package emits a light beam to a tabletop and the tabletop reflects the light beam to the image sensor device. A method for manufacturing the optical navigation sensor module is also provided. This optical navigation sensor module of an optical mouse may reduce the optical loss, improve the sensitivity of the optical mouse and promote the production yield.

### BACKGROUND OF THE INVENTION

1. Field of the Invention

The present invention relates to an optical mouse, and more particularly to an optical navigation sensor module of an optical mouse and a method for manufacturing the same.

2. Description of the Prior Art

An optical mouse captures images of a surface whereon an optical mouse is placed with an inner image sensor. Movements of the mouse cause variation to the captured images, thereby leading to corresponding movements of a cursor on the screen.

A conventional optical navigation sensor module of an optical mouse uses a transistor outline (TO) package or a lamp package for light-emitting chips, wherein a TO package is costly as opposed to a lamp package. Although a lamp package is cheaper, yield and accuracy thereof is poor; volume required for the package is larger. A conventional optical navigation sensor module 30 as shown in FIG. 1 utilizes a lamp package VCSEL as a lighting source, wherein a VCSEL 32 is arranged on an electric circuit 34; an image sensor device 36 is arranged inside a holder 38; a lens component 40 is arranged between the VCSEL 32 and the image sensor 36, whereby a light beam 42 emitted from the VCSEL 32 converges through the lens component 40 and is projected to a tabletop 44. Furthermore, the light beam 42 reflected from the tabletop 44 converges through the lens component 40 and forms an image on the image sensor device 36. In this case, because the VCSEL 32 requires large volume for package, the light beam 42 emitted from the VCSEL 32 must undergo a long optical path to arrive the tabletop 44 and then be reflected to the image sensor device 36, which may easily lead to optical loss in the whole optical path.

Another conventional optical navigation sensor module of an optical mouse, wherein the optical components such as light-emitting chips, image sensor devices and lens are packaged in the same IC device, enables the IC device to have the same functions as an optical navigation sensor module of an optical mouse has. However, this type of package is costly. Once the light-emitting chips, image sensor devices or lens start to wear, it is impossible to only replace one of them but necessary to replace all components and package them again, which causes a huge waste of components and devices; cost of production cannot be reduced.

### SUMMARY OF THE INVENTION

The present invention relates to an optical navigation sensor module of an optical mouse and a method for manufacturing the same, wherein SMD packages are used for light-emitting chip packages; light-emitting chip packages and image sensor devices are arranged on the same substrate to reduce the size of the optical navigation sensor module of an optical mouse, thereby reducing the distance from the optical navigation sensor module of an optical mouse to an outside surface and reducing optical loss of a light beam in the whole optical path to enhance sensitivity of an optical mouse and improve production yield.

It is an objective of the present to provide an optical navigation sensor module of an optical mouse which is capable of saving power, saving energy and protecting eyes.

It is an objective of the present invention to provide an optical navigation sensor module of an optical mouse, wherein a light-emitting chip package using a SMD package is easy for replacement and has the advantages of high yield and high accuracy.

In order to achieve the objectives mentioned above, an optical navigation sensor module of an optical mouse according to an embodiment of the present invention comprises: a substrate with a lower surface; an image sensor device arranged on the lower surface of the substrate; and an emitting chip package using a SMD package, electrically connected to the lower surface of the substrate, for emitting a light beam to a outside surface. The light beam will be reflected to the image sensor device by the outside surface.

A method for manufacturing an optical navigation sensor module of an optical mouse according to an embodiment of the present invention comprises: using surface mounted technology to package an emitting chip to form a light-emitting chip package; and electrically connecting the light-emitting chip package and an image sensor device to a lower surface of a substrate.

The objective, technologies, features and advantages of the present invention will become more apparent from the following description in conjunction with the accompanying drawings, wherein certain embodiments of the present invention are set forth by way of illustration and examples.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic diagram illustrating the structure of a conventional optical navigation sensor module using a lamp package VCSEL as a lighting source;

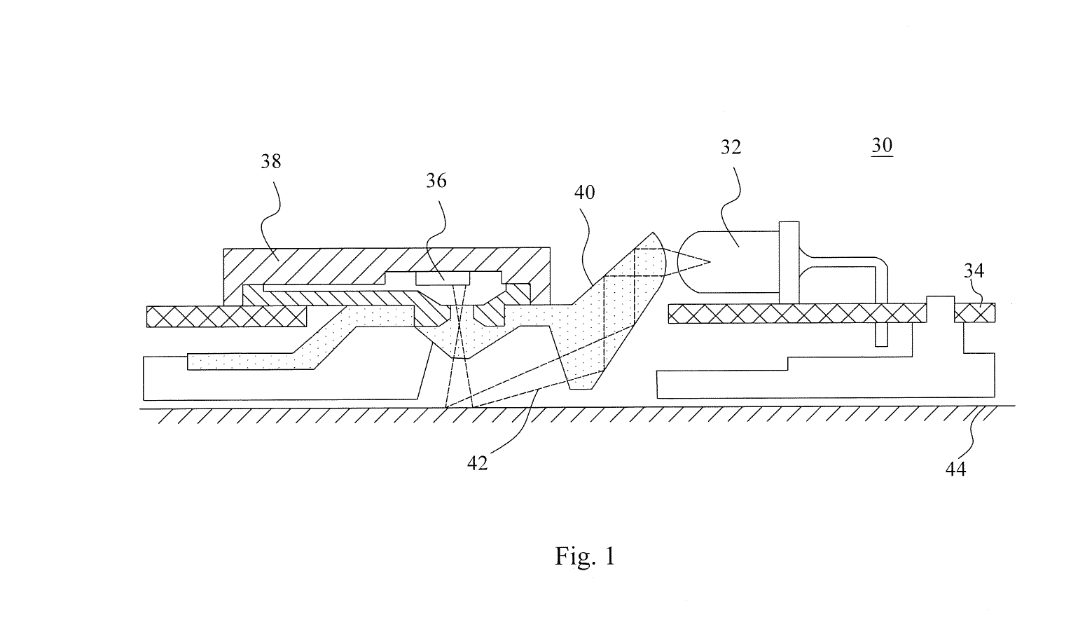

FIG. 2 is a schematic diagram illustrating the structure of an optical navigation sensor module of an optical mouse according to an embodiment of the present invention;

FIG. 3 is a schematic diagram illustrating an optical path of an optical navigation sensor module of an optical mouse according to an embodiment of the present invention; and

FIG. 4 is a schematic flowchart of a method for manufacturing an optical navigation sensor module of an optical mouse according to another embodiment of the present invention.

### DESCRIPTION OF THE PREFERRED EMBODIMENT

The detail description is provided below and the preferred embodiments described are only for the purpose of description rather than for limiting the present invention.

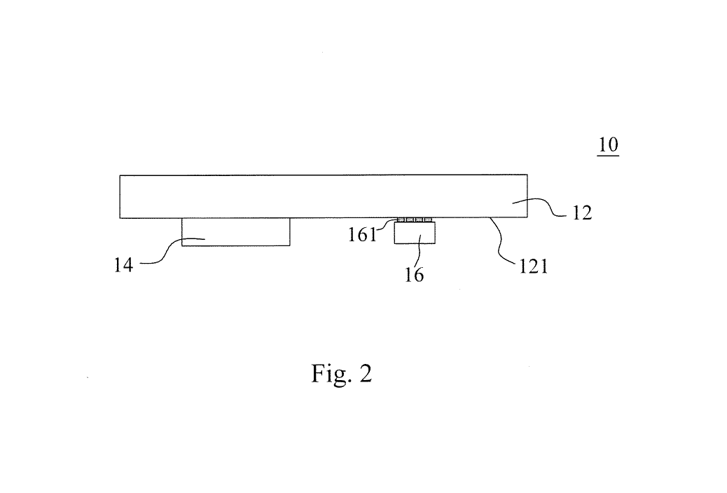

FIG. 2 is a schematic diagram illustrating the structure of an optical navigation sensor module of an optical mouse according to an embodiment of the present invention. In this embodiment, an optical navigation sensor module of an optical mouse 10 comprises a substrate 12, which is a circuit board in an embodiment with a lower surface 121; an image sensor device 14, which is arranged on the lower surface 121 of the substrate 12, for example, is an electric charge coupling device or a Complementary Metal-Oxide-Semiconductor image sensor device; and a light-emitting chip package 16, electrically connected to the lower surface 121 of the substrate 12, wherein the light-emitting chip package 16 is a SMD package and multiple solder joints thereof are arranged on the lower surface 121 of the substrate 12 by welding. In an embodiment, the light-emitting chip package 16 is a SMD package with VCSEL chips.

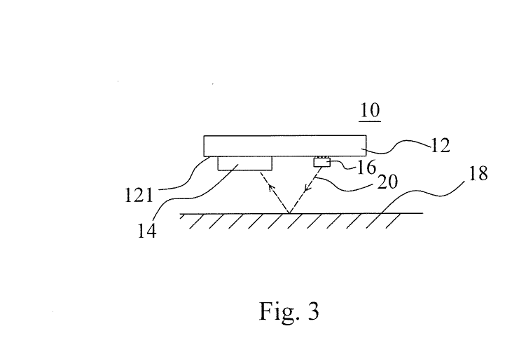

Continuing the description above, an optical mouse (not shown), which uses the optical navigation sensor module 10 of an optical mouse as shown in FIG. 3, is placed on a outside surface 18 (e.g. tabletop), wherein the light-emitting chip package 16 emits a light beam 20 to the outside surface 18; the outside surface 18 reflects the light beam 20 to the image sensor device 14 so as to capture the image of the outside surface 18 via the image sensor device 14. Thus, when users move the optical mouse, images captured by the image sensor device 14 vary correspondingly.

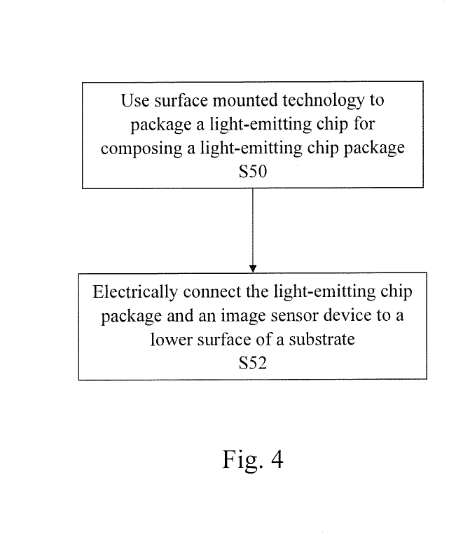

FIG. 4 represents a schematic flowchart depicting a method for manufacturing an optical navigation sensor module of an optical mouse according to an embodiment of the present invention. A method for manufacturing an optical navigation sensor module of an optical mouse comprises: using surface mounted technology to package a light-emitting chip for composing a light-emitting chip package, which is the step S50 and wherein the light-emitting chip is a VCSEL chip in an embodiment; and electrically connecting this chip package and an image sensor device to a lower surface of a substrate, which is the step S52 and wherein the substrate is a circuit board and the chip package is electrically connected to the lower surface of the substrate by welding.

The present invention utilizes the light-emitting chip package 16, which is a SMD package, as a lighting source; the light-emitting chip package 16 and the image sensor device 14 are arranged on the lower surface 121 of the same substrate 12. Because the light-emitting chip package 16 is micro-sized, all components contained in the optical navigation sensor module of an optical mouse 10 can be downsized and therefore the distance between the optical navigation sensor module of an optical mouse 10 and the outside surface 18 can be shortened so as to reduce optical loss in the whole optical path and enhance sensitivity of the optical mouse to suit different types of outside surfaces. Furthermore, because the whole optical path is shortened, accuracy requirements for installing the light-emitting chip package 16 and the image sensor device 14 onto the substrate 12 can be lowered and thus production yield can be promoted. Meanwhile, shortening of the optical path also can prevent conventional use for optical components such as lens. Additionally, reduction of optical loss further lowers output power of the lighting source to achieve the effects of saving power and energy. Also since the light-emitting chip package 16 is a SMD package with VCSEL chips, low-power use thereof can protect user eyes and therefore in line with product safety regulations.

On the other side, since each light-emitting chip package 16 is screened and examined, yield thereof will be guaranteed and therefore the optical navigation sensor module of an optical mouse 10, which is composed of the light-emitting chip package 16 and the image sensor device 14, is guaranteed for production yield. Once the light-emitting chip package 16 of the optical navigation sensor module of an optical mouse 10 needs to be replaced, only the solder joints 161 of the light-emitting chip package 16 on the substrate 12 should be desoldered for replacement without the need of replacement for the image sensor device 14 at the same time. Comparing with the conventional process which integrates the light-emitting chip, the image sensor device, and the lens into an IC package and all the components must be replaced and packaged again if a single component has worn out, the present invention has the advantages of easy replacement and high production yield for the optical navigation sensor module of an optical mouse. The optical navigation sensor module of an optical mouse according to another embodiment of the present invention, a lens can be independently arranged under the image sensor device and the light-emitting chip package based on user requirements, wherein the light-emitting chip package can be replaced without affecting the lens.

In summary, the present invention utilizes a SMD package type of light-emitting chip package as a lighting source of an optical mouse, which makes the optical navigation sensor module of an optical mouse capable of micronization. Besides, the light-emitting chip package and the image sensor device are arranged on the same circuit board, which can shorten the distance between the optical navigation sensor module of an optical mouse and the outside surface, to reduce optical loss in the whole optical path so as to enhance sensitivity of the optical mouse and achieve the effects of saving power, saving energy and protecting eyes.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. An optical navigation sensor module of an optical mouse comprising:
a substrate with a lower surface;
an image sensor device, arranged on the lower surface of the substrate; and
a light-emitting chip package using a SMD package, electrically connected to the lower surface of the substrate, wherein the light-emitting chip package emits a light beam to an outside surface and the outside surface reflects the light beam to the image sensor device.

2. The optical navigation sensor module of an optical mouse according to claim 1, wherein the light-emitting chip package is a VCSEL package.

3. The optical navigation sensor module of an optical mouse according to claim 1, wherein the substrate is a circuit board.

4. The optical navigation sensor module of an optical mouse according to claim 1 further comprising a lens, arranged under the image sensor device and the light-emitting chip package.

5. The optical navigation sensor module of an optical mouse according to claim 1, wherein the light-emitting chip package is electrically connected to the lower surface of the substrate by welding.

6. A method for manufacturing an optical navigation sensor module of an optical mouse comprising:
using surface mounted technology to package a light-emitting chip to form a light-emitting chip package; and
electrically connecting the light-emitting chip package and an image sensor device to a lower surface of a substrate.

7. The method for manufacturing the optical navigation sensor module of an optical mouse according to claim 6, wherein the light-emitting chip package is a VCSEL chip.

8. The method for manufacturing the optical navigation sensor module of an optical mouse according to claim 6, wherein the light-emitting chip package is electrically connected to the lower surface of the substrate by welding.

9. The method for manufacturing the optical navigation sensor module of an optical mouse according to claim 6, wherein the substrate is a circuit board.
